(19) United States
(12) Patent Application Publication
(10) Pub. No.: US 2015/0243849 A1
(43) Pub. Date: Aug. 27, 2015

(54) QUANTUM DOT LIGHT-EMITTING DIODE DISPLAY DEVICE

(71) Applicant: Christian Stroetmann, Moers (DE)

(72) Inventor: Christian Stroetmann, Moers (DE)

(21) Appl. No.: 14/579,655

(22) Filed: Dec. 22, 2014

(30) Foreign Application Priority Data
Dec. 23, 2013 (DE) 20-2013-011-466.5

(51) Int. Cl. H01L 33/40; H01L 33/06; H01L 27/12

(52) U.S. Cl. CPC H01L 33/40; H01L 27/124; H01L 33/06

(57) ABSTRACT

A quantum dot light-emitting diode display device is disclosed which includes: a substrate; a light emission diode layer stacked on the substrate and configured to emit light, the light emission diode layer including a cathode, a quantum dot light-emitting layer formed on the cathode to include quantum dots, and an anode formed on the quantum dot light-emitting layer; at least one electrode of the quantum dot light emission diode layer based on carbon; at least one scan line; at least one data line; at least one power line; and a field-effect transistor connected to the light emission diode layer.

### CROSS-REFERENCE TO RELATED APPLICATION

This application claims the benefit of the German Utility Model Application No. 20-2013-011-466.5, filed Dec. 23, 2013, and entitled “Elektronische Anzeige, die auf der nanohalbleiterkristallbasierten beziehungsweise quantenpunktbaseirten, lichtemittierenden Diode (kurz QLED) basiert”, which is hereby incorporated by reference in its entirety.

### BACKGROUND

1. Field of the Disclosure

The present application relates to quantum dot light-emitting diode display devices.

2. Description of the Related Art

Devices for displaying information are being widely developed. The display devices include several types, such as liquid crystal display (LCD) devices, organic light-emitting diode display (OLEDD) devices, quantum dot light-emitting diode display (QLEDD) devices, electrophoresis display devices, field emission display (FED) devices, and plasma display panel (PDP) devices.

The display devices also include special types, such as transparent and also flexible light-emitting diode display devices with scan lines, data lines, and power lines based on graphene, and OLEDD devices with nanowire transistors.

Among these display devices, QLEDD devices have the features of lower power consumption, smaller size, specifically thinner dimension, lighter weight, higher brightness, and wider viewing angle compared to LCD devices. Also, QLEDD devices emit light in very specific gaussian distributions. This can result in a display device with visibly more accurate colors compared to OLEDD devices.

A discussion and structures of a general QLEDD device has been given in for example the U.S. Pat. No. 8,552,416, issued Oct. 8, 2013, and entitled “Quantum Dot Lght Emitting Diode Device and Display Device Therewith”, which is hereby incorporated herein by reference.

A discussion and structures of carbon based, quantum dot light-emitting diode devices has been given by the inventor in for example the German Utility Model Application No. 20 2013 009 082.0, filed Oct. 15, 2013, and entitled “Diode”, which is hereby incorporated herein by reference.

In general, display devices of the related art also have the following problems.

Firstly, the power consumption of QLEDD devices on the one hand and on the other hand display devices with individual components, which are based on a carbon allotrope or/and nanostructed, can be improved.

Secondly, display devices are developed, that display images with a higher resolution. For being able to increase the display resolution even further, the individual components of the display devices must be constructed with smaller structures.

Thirdly, transparent variants of QLEDD devices are not truly transparent, due to the sizes of their scan lines, data lines, and power lines, their transistors, or/and their light-emitting components. As a result a see-through view on objects behind a QLEDD appears blurred or/and darkened to a user. This deficiency makes such display devices unusable for such applications, that demand or even make mandatory an unimpaired see-through view with a high grade of transparency and sharpness.

In attempts to overcome the above-mentioned disadvantages of such display devices, a variety of technology research and development are being executed. But the related art is impossible to apply to a next generation of electric power efficient, high resolution, truly transparent see-through, or/and flexible light-emitting display devices. For example, in order to improve the quality of transparency and sharpness of a see-through display device simply using thinner and smaller individual components is not enough.

In view of these points, alternative methods capable of constructing QLEDD devices are being developed.

### BRIEF SUMMARY

Accordingly, embodiments of the present application are directed to a quantum dot light-emitting diode display (QLEDD) device, that substantially obviates one or more of problems due to the limitations and disadvantages of the related art.

The embodiments are to provide a QLEDD device, that is adapted to improve the electric power efficiency, increase the display resolution, increase the refresh rate, or/and enhance the quality of see-through transparency and sharpness of a QLEDD device.

Additional features and advantages of the embodiments will be set forth in the description which follows, and in part will be apparent from the description, or may be learned by practice of the embodiments. The advantages of the embodiments will be realized and attained by the structure particularly pointed out in the written description and claims hereof as well as the appended drawings.

To achieve these objects and other advantages in accordance with the purpose of the invention, as embodied and broadly described herein, and according to a first general aspect of the present embodiments, a QLEDD device includes: a substrate respectively support material; a light emission diode layer stacked on the substrate and configured to emit light, the light emission diode layer including a cathode, a quantum dot light-emitting layer formed on the cathode to include quantum dots, and an anode formed on the quantum dot light-emitting layer; at least one electrode of the quantum dot light emission diode layer being based on carbon; at least one scan line; at least one data line; at least one power line; and a field-effect transistor connected to the light emission diode layer.

Other systems, methods, features and advantages, objects, and features of the disclosure will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with the embodiments. It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated herein and constitute a part of this application, illustrate embodiment(s) of the disclosure and together with the description serve to explain the principle of the disclosure. In the drawings:

FIG. 1 is a block diagram showing a quantum dot light-emitting diode display (QLEDD) device according to an embodiment of the present invention;

FIG. 2 illustrates a planar view showing an QLEDD device according to a first embodiment of the present invention;

FIGS. 3(a) and 3(b) respectively illustrate a single pixel region of a QLEDD device taken in a circle B in FIG. 2 in accordance with an embodiment of the present invention;

FIGS. 4(a) and 4(b) respectively illustrate a single pixel region of a QLEDD device taken in a circle B in FIG. 2 in accordance with an embodiment of the present invention that has a field-effective transistor constructed orthogonal to the substrate;

FIG. 5 illustrates a cross-sectional view showing a section of a QLEDD device taken along a line A-A′ in FIG. 2 in accordance with a first preferred embodiment of the present invention;

FIG. 6 illustrates a cross-sectional view showing a section of a QLEDD device taken along a line A-A′ in FIG. 2 in accordance with a second preferred embodiment of the present invention;

FIG. 7 illustrates a cross-sectional view showing a section of a QLEDD device taken along a line A-A′ in FIG. 2 in accordance with a third preferred embodiment of the present invention;

FIG. 8 illustrates a cross-sectional view showing a section of a QLEDD device taken along a line A-A′ in FIG. 2 in accordance with a fourth preferred embodiment of the present invention;

FIG. 9 illustrates a cross-sectional view showing a section of a QLEDD device taken along a line A-A′ in FIG. 2 in accordance with a fifth preferred embodiment of the present invention;

FIG. 10 illustrates a cross-sectional view showing a section of a QLEDD device taken along a line A-A′ in FIG. 2 in accordance with a sixth preferred embodiment of the present invention;

FIG. 11 illustrates a cross-sectional view showing a section of a QLEDD device taken along a line A-A′ in FIG. 2 in accordance with a seventh preferred embodiment of the present invention;

FIG. 12 illustrates a perspective view showing a section of a QLEDD device;

FIG. 13 illustrates a perspective view showing a section of a QLEDD device;

FIGS. 14(a), 14(b), and 14(c) respectively illustrate a section of a QLEDD device;

FIG. 15 illustrates a perspective view showing a section of a QLEDD device;

FIGS. 16(a), 16(b), and 16(c) respectively illustrate a section of a QLEDD device;

FIG. 17 illustrates a planar view showing a section of a QLEDD device;

FIG. 18 illustrates a perspective view showing a section of a QLEDD device;

FIGS. 19(a) and 19(b) respectively illustrate a section of a QLEDD device; and

FIG. 20 illustrates a cross-sectional view showing a section of an application of a QLEDD device.

### DETAILED DESCRIPTION OF THE INVENTION

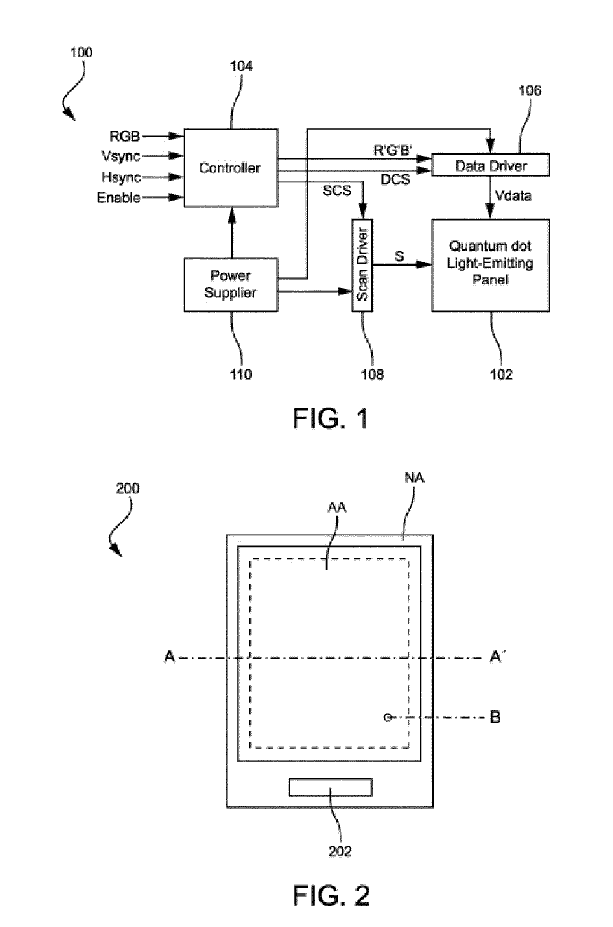

FIG. 1 is a block diagram showing a quantum dot light-emitting diode display (QLEDD) device according to an embodiment of the present disclosure.

Referring to FIG. 1, the QLEDD device 100 according to an embodiment of the present disclosure can include a quantum dot light-emitting panel 102, a controller 104, a data driver 106, a scan driver 108, and a power supplier 110.

The data driver 106 can apply data voltages Vdata to the quantum dot light-emitting panel 102.

The scan driver 108 can apply scan signals S to the quantum dot light-emitting panel 102.

The power supplier 110 can apply a plurality of drive voltages to the controller 104, the data driver 106, and the scan driver 108.

Although it is not shown in the drawing, the quantum dot light-emitting panel 102 can include a plurality of scan lines, a plurality of data lines, and a plurality of power lines. The scan lines and the data lines crossing each other can define a plurality of pixel regions. Each pixel region can electrically connected to one of the scan lines, one of the data lines, and one of the power lines.

For example, each scan line can be electrically connected with the plurality of pixel regions arranged in a horizontal direction. Each data line can be electrically connected with the plurality of pixel regions arranged in a vertical direction.

As such, the scan signal S, the data voltage Vdata, and a supply voltage can be applied to each of the pixel regions. In detail, the scan signal S can be applied to the pixel region through one of the scan lines, the data voltage Vdata can be applied to the pixel region through one of the data lines, and the supply voltage can be applied to the pixel region through one of the power lines.

FIG. 2 is a planar view showing a QLEDD device 200 according to an embodiment of the disclosure.

Referring to FIG. 2, the QLEDD device according to an embodiment of the present disclosure can include a display area AA, which is used to display an image, and a non-display area NA, in which any image is not displayed. The display area AA can be formed in the central area of the QLEDD device. The non-display area NA can be positioned in the peripheral area around the display area AA.

The QLEDD device can further include a driver chip 202, which is formed in the non-display area NA. The driver chip 202 can include at least one of the controller, the data driver, and the scan driver. Also, the driver chip 202 can apply drive signals to pixel regions, only shown in the illustration is a pixel region B, within the display area through a plurality of lines.

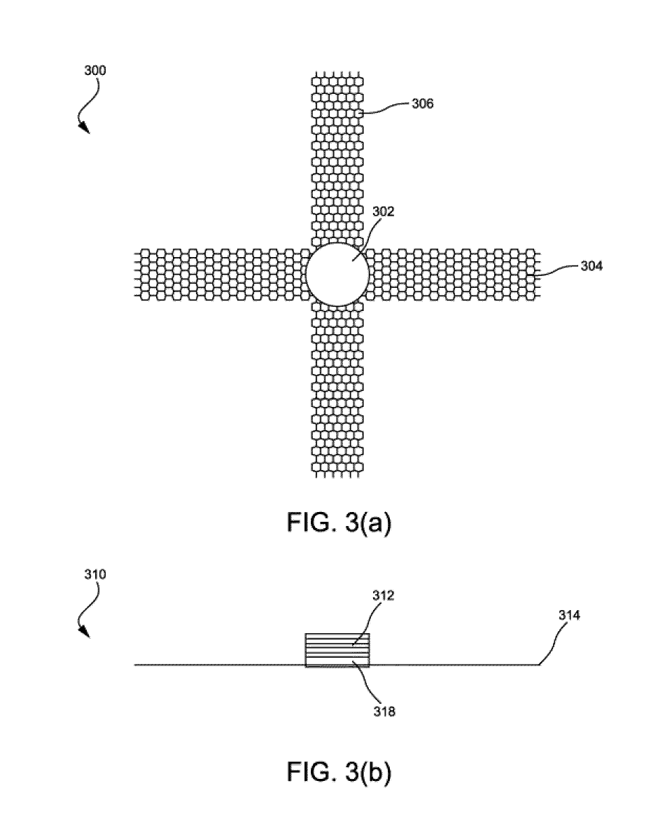

FIG. 3(a) illustrates a planar view and FIG. 3(b) illustrates a cross-sectional view showing a single pixel region of a QLEDD device in a circle B of FIG. 2 in accordance with an embodiment of the present invention, that has a field-effective transistor (FET) constructed planar to the substrate.

Referring to FIG. 3(a), a carbon based, quantum dot light-emitting diode device 302 according to an embodiment of the disclosure includes a scan line based on graphene 304 and a data line based on graphene 306. The FET 318 shown in FIG. 3(b) is not shown in this view for clarity of illustration.

Referring to FIG. 3(b), a carbon based, quantum dot light-emitting diode device 312 according to an embodiment of the disclosure includes a scan line based on graphene 314 and an FET 318. The data line based on graphene 316 shown in FIG. 3(a) is not shown in this view for clarity of illustration.

In accordance therewith, very thin and energy efficient pixel structures can be created.

Also, for a sufficient brightness of the display device the very thin lines must be able to transport enough electric energy without being disassembled. By using a carbon allotrope as material for the lines this requirement can be fulfilled.

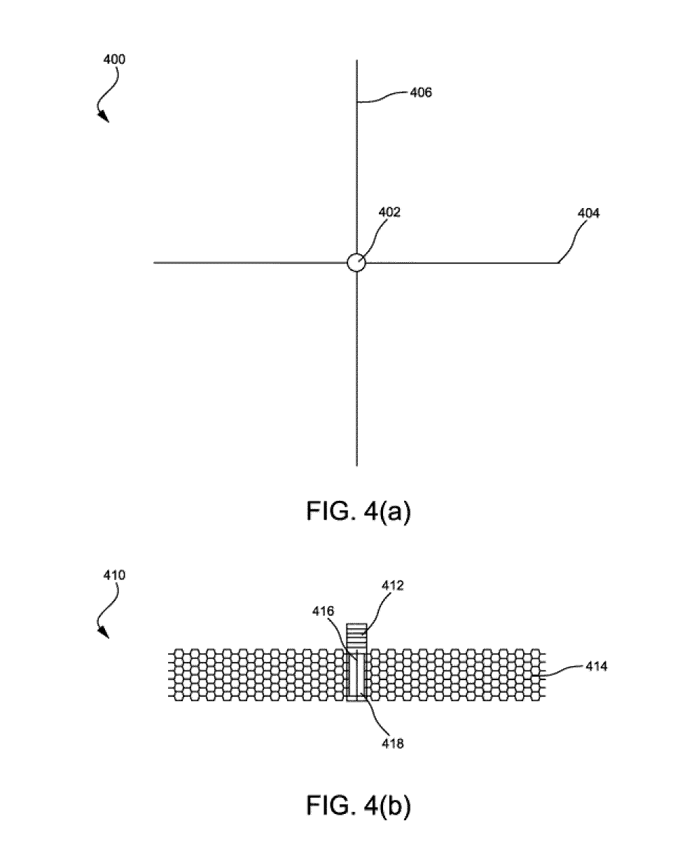

FIG. 4(a) illustrates a planar view and FIG. 4(b) illustrates a cross-sectional view showing a single pixel region of a QLEDD device in a circle B of FIG. 2 in accordance with an embodiment of the present invention, that has a field-effective transistor (FET) constructed orthogonal to the substrate. Referring to FIG. 4(a), a carbon based, quantum dot light-emitting diode device 402 according to an embodiment of the disclosure includes a scan line based on graphene 404 and a data line based on graphene 406. The FET 418 shown in FIG. 4(b) is not shown in this view for clarity of illustration.

Referring to FIG. 4(b), a carbon based, quantum dot light-emitting diode device 412 according to an embodiment of the disclosure includes a scan line based on graphene 414, a data line based on graphene 416, and an FET 418.

In accordance therewith, very thin and energy efficient pixel structures can be created.

Furthermore, in the case that for a QLEDD device also its plurality of pixel regions are being arranged on the display area with more spacing between each other and in addition brighter shinning carbon based, quantum dot light-emitting diode devices are being used, a user's eye should be unable to see the display device components in a display area AA shown in FIG. 2 without impairing the imaging quality. As a specific result, the quality of transparency and sharpness of a see-through display device, which is isotropic on the macroscopic scale, can be enhanced.

It should be trivial for any person skilled in the art, to which the invention appertains, to use power lines based on graphene as well.

It should also be trivial for any person skilled in the art to substitute the lines based on the carbon allotrope graphene, as shown in the FIGS. 3(a), 3(b), 4(a), and 4(b), with lines based on the carbon allotrope carbon nanotube. As such, the repetition of related figures and descriptions will be omitted.

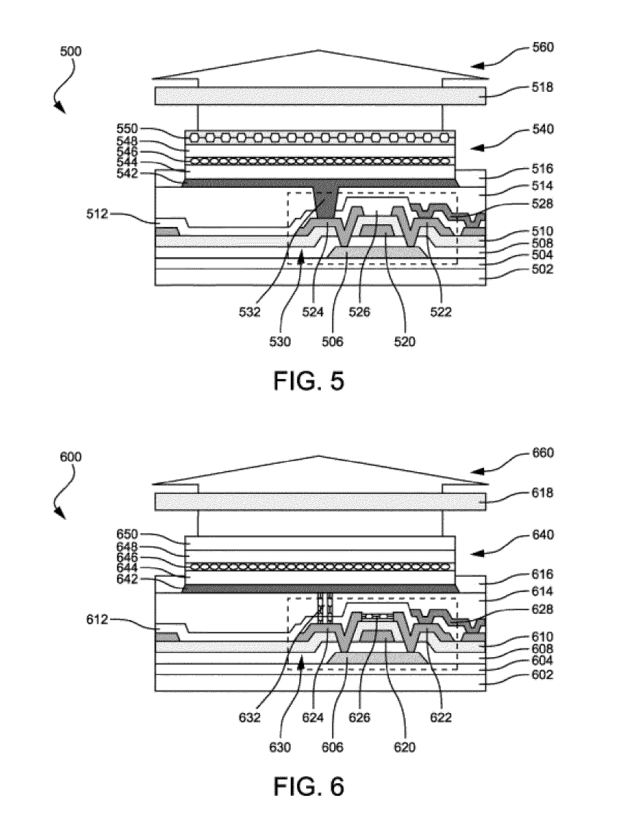

FIG. 5 illustrates a section of a display device 500 in accordance with a first preferred embodiment of the present invention.

Referring to FIG. 5, the display device, which is an upward light emission type, includes a field-effect transistor (FET) 530 and a light emission layer 540 to emit a beam of light 560.

The light emission layer 540 includes a cathode 542 on a substrate 502, a quantum dot light-emitting layer 546 formed on the cathode 542 to have quantum dots, and a transparent anode 550 on the quantum dot light-emitting layer 546. The cathode 542 is connected to the FET 530.

The display device can further include an electron transport layer 544 between the cathode 542 and the quantum dot light-emitting layer 546, and a hole transport layer 548 between the quantum dot light-emitting layer 546 and the anode 550.

The anode 550 is formed of a single transparent conductive metal nanowire or an array of transparent conductive metal nanowires, such as a silver nanowires or copper nanowires for example, covered with graphene for example. By using a metal nanowire or an array of metal nanowires covered with graphene as transparent anode 550 a carbon based, quantum dot light-emitting diode can be fabricated in an easier way by applying large-area synthesis approaches, including chemical vapor deposition for example, which again can be used to fabricate a flexible, transparent QLEDD device. The quantum dot light-emitting layer 546 having the quantum dots can be formed at a pixel region of the substrate 502 selectively, enabling to form the hole transport layer 548 and the electron transport layer 544 to have widths the same with a width of the quantum dot light-emitting layer 546, or on the substrate 502 overlapped with the quantum dot light-emitting layer 546 as shown in the drawing. In a latter case, the hole transport layer 548 and the electron transport layer 544 can be formed on an entire surface of the substrate 502.

The anode 550 is formed on the hole transport layer 548, and depending on cases, if the hole transport layer 548 is formed on an entire surface of the substrate 502, the anode 550 can be formed together with the hole transport layer 548 on an entire surface of the substrate.

In addition, opposite to the substrate 502 an encapsulation substrate 518 can be formed for capping and protection of the substrate 502. And, though not shown, sealant is placed between edges of the encapsulation substrate 518 and the substrate 502 for bonding the two substrates. This is for protecting the hole transport layer 548 and the electron transport layer 544 from water or other external environment, when the hole transport layer 548 or the electron transport layer 544 is formed of an organic material.

The FET 530 is formed at every crossed portion of gate lines (not shown) and data lines (not shown) running perpendicular to each other to form a pixel region at every crossed portion thereof, and includes a gate electrode 520 projected from the gate line, a data electrode 528 projected from the data line, a semiconductor layer 508 under the gate electrode 520, and a source electrode 522 and a drain electrode 524 positioned on opposite sides of the gate electrode 520 connected to both sides of the semiconductor layer 508. In this instance, the source electrode 522 is connected to the data electrode 528, and the drain electrode 524 is connected to the cathode 542 by the cathode's lead 532.

A similar QLEDD device and a related fabrication method are disclosed in the U.S. Pat. No. 8,552,416, issued Oct. 8, 2013, and entitled “Quantum Dot Lght Emitting Diode Device and Display Device Therewith”, which does not comprise a carbon based electrode or/and carbon based transistor, and that is hereby referenced.

However, the carbon based, quantum dot light emission diode layer 546 and FET 530 are not limited to the structure mentioned above. Many other possibilities exist for a person skilled in the arts to construct a carbon based, quantum dot light-emitting diode device with an FET. For example, more parts of an FET can be based on carbon allotropes, carbon based compounds, and carbon based composites, like e.g. the base material of an FET can be formed of silicon carbid, and the gate electrode 520, source electrode 522, and drain electrode 524 can be made out of on a carbon allotrope, a metal nanowire, a semiconductor nanowire, a composite consisting of a nanowire covered with graphene, or a composite consisting of a carbon nanowire compounded with a metal.

Also, the data line (not shown), the data electrode 528, and the source electrode 522 can be formed as one unit.

In a similar way, the drain electrode 524 of the FET and the lead of the cathode 532 or the drain electrode 524 and the whole cathode 542 can be formed as one unit based on a carbon allotrope, carbon based compound, or carbon based composite, including compounds, like e.g. graphene and silicon carbid, and composites consisting of a nanowire covered with graphene, or a carbon nanowire compounded with a metal.

Unexplained reference numerals of 504 denotes a buffer layer, 506 denotes a first interlayer insulating film, 510 denotes a gate insulating film, 512 denotes a second interlayer insulating film, 514 denotes a third interlayer insulating film, and 516 denotes a protective film.

Furthermore, it is to be understood that any person skilled in the art should be able to construct a similar QLEDD device as a bottom light emission type with the non-transparent cathode and the transparent anode exchanged to a transparent cathode and a non-transparent anode.

Moreover, the section in FIG. 5 illustrates only one pixel region. In this instance, if it is assumed that the quantum dot light-emitting layer emits a color light, other pixel region has a quantum dot light-emitting layer which emits other color light, enabling to produce many color lights.

FIG. 6 illustrates a section of a QLEDD device 600 in accordance with a second preferred embodiment of the present invention.

Referring to FIG. 6, the display device includes a field-effect transistor (FET) 630 and a light emission layer 640 to emit a beam of light 660.

Because the display device in accordance with the second preferred embodiment of the present invention has the FET's channel material exchanged with a single carbon nanotube or an array of carbon nanotubes 626, the cathode 642 is connected to the drain electrode 624 by the cathode's lead 632 consisting of a carbon nanotube or an array of carbon nanotubes, and the transparent anode 650 must not consist of a transparent conductive metal nanowire covered with graphene, with parts except above left identical to the first embodiment shown in FIG. 5, description of identical parts, fabrication method, and different ways of construction will be omitted.

Unexplained reference numerals of 602 denotes a substrate, 604 denotes a buffer layer, 606 denotes a first interlayer insulating film, 608 denotes a semiconductor layer, 610 denotes a gate insulating film, 612 denotes a second interlayer insulating film, 614 denotes a third interlayer insulating film, and 616 denotes a protective film, 618 denotes an encapsulation substrate, 620 denotes a gate electrode, 622 denotes a source electrode, and 628 denotes an electrode line.

Further unexplained reference numerals of 644 denotes an electron transport layer, 646 denotes a quantum dot light-emitting layer, and 648 denotes a hole transport layer.

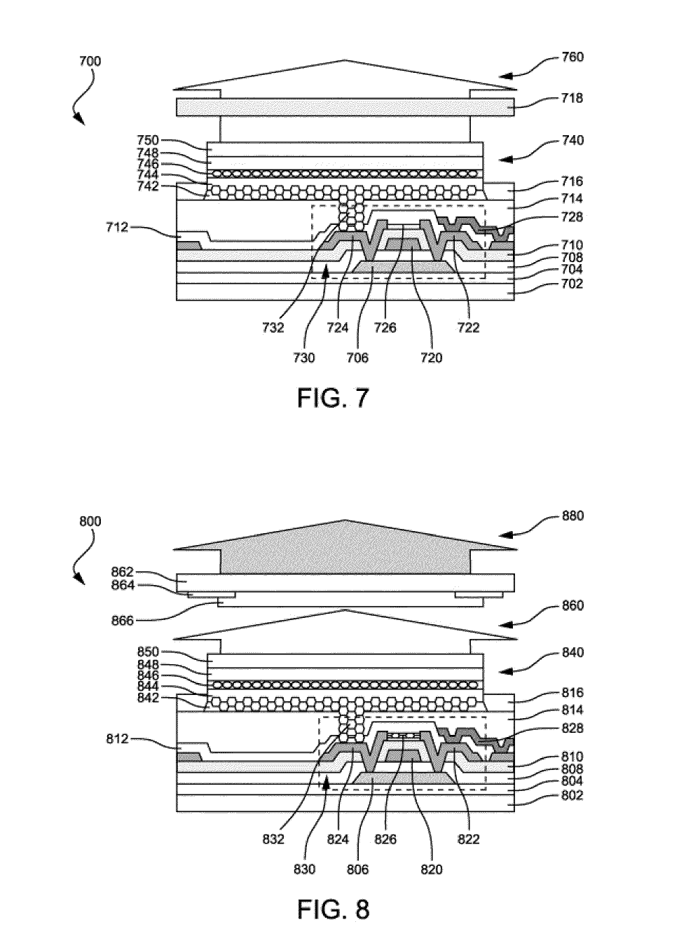

FIG. 7 illustrates a section of a QLEDD device 700 in accordance with a third preferred embodiment of the present invention.

Referring to FIG. 7, the display device includes a field-effect transistor (FET) 730 and a light emission layer 740 to emit a beam of light 760.

Because the display device in accordance with the third preferred embodiment of the present invention has the FET's channel material exchanged with a single graphene nanoribbon 726, and the cathode's 742 material exchanged with a single graphene nanoribbon or layered graphene sheets 732, with parts except above left identical to the second embodiment shown in FIG. 6, description of identical parts, fabrication method, and different ways of construction will be omitted.

Unexplained reference numerals of 702 denotes a substrate, 704 denotes a buffer layer, 706 denotes a first interlayer insulating film, 708 denotes a semiconductor layer, 710 denotes a gate insulating film, 712 denotes a second interlayer insulating film, 714 denotes a third interlayer insulating film, and 716 denotes a protective film, 718 denotes an encapsulation substrate, 720 denotes a gate electrode, 722 denotes a source electrode, 724 denotes a drain electrode, and 728 denotes an electrode line.

Further unexplained reference numerals of 744 denotes an electron transport layer, 746 denotes a quantum dot light-emitting layer, 748 denotes a hole transport layer, and 750 denotes a transparent anode.

FIG. 8 illustrates a section of a QLEDD device 800 in accordance with a fourth preferred embodiment of the present invention.

Referring to FIG. 8, the display device includes a carbon based cathode 842 on a first substrate 802, a quantum dot light-emitting layer 846 formed on the cathode 842 to have quantum dots, a transparent anode 850 on the quantum dot light-emitting layer 846, a field-effect transistor (FET) 830 formed on the first substrate 802 and connected to the cathode 842, and a second substrate 862 formed opposite to the first substrate 802 to have a color filter layer 866.

Because the display device in accordance with the fourth preferred embodiment of the present invention has the FET's channel material exchanged with a single carbon nanotube or an array of carbon nanotubes 826, with parts except above left identical to the third embodiment shown in FIG. 7, description of identical parts, fabrication method, and different ways of construction will be omitted.

Unexplained reference numerals of 804 denotes a buffer layer, 806 denotes a first interlayer insulating film, 808 denotes a semiconductor layer, 810 denotes a gate insulating film, 812 denotes a second interlayer insulating film, 814 denotes a third interlayer insulating film, and 816 denotes a protective film, 820 denotes a gate electrode, 822 denotes a source electrode, 824 denotes a drain electrode, 826 denotes a single carbon nanotube or an array of carbon nanotubes as FET channel, and 828 denotes an electrode line.

Further unexplained reference numerals of 844 denotes an electron transport layer, and 848 denotes a hole transport layer.

However, with regard to the quantum dot light-emitting layer 846 of the light emission layer 840, though the quantum dot light-emitting layer in the first, second, and third embodiments include quantum dots which emit primary colors of R, G, and B, the quantum dot light-emitting layer 846 in the fourth embodiment includes quantum dots which emit a white color. However, the quantum dot light-emitting layer 846 in the fourth embodiment can include red (R) quantum dots, green (G) quantum dots, and blue (B) quantum dots mixed in an equal ratio, or can include a stack of an R quantum dot light-emitting layer, a G quantum dot light-emitting layer, and a B quantum dot light-emitting layer.

The color filter layer 866 is positioned on the second substrate 862, which is opposite to the quantum dot light-emitting layer 846, and a black matrix layer 864 is formed on the second substrate 862 opposite to regions excluding the pixel region. As shown, the color filter layer 866 can overlap with the black matrix layer 864 at both edges thereof, and the color filter layer 866 can have color filters of different colors matched to the pixel regions respectively to display colors different from one another. For an example, R, G, B color filters are formed respectively matched to different pixel regions for enabling to change a white color light emitted to the underlying first substrate 802 to various colors.

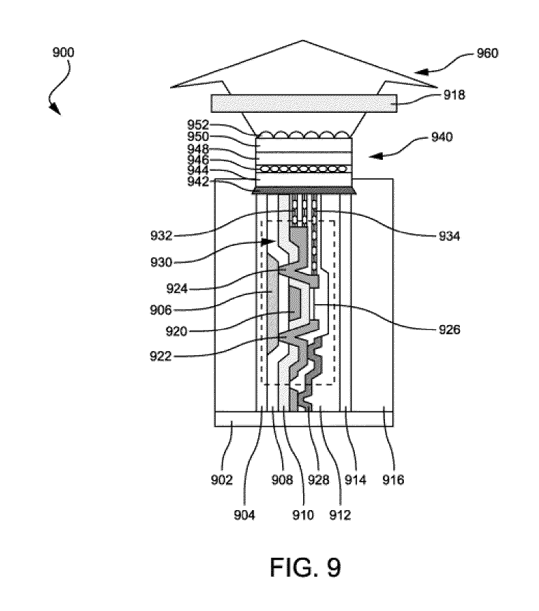

FIG. 9 illustrates a section of a QLEDD device 900 in accordance with a fifth preferred embodiment of the present invention.

Referring to FIG. 9, the display device includes a field-effect transistor (FET) 930 and a light emission layer 940 to emit a beam of light 960.

Because the display device in accordance with the fifth preferred embodiment of the present invention has the FET 930 structure formed orthogonal to the substrate 902, the FET's channel exchanged with a single graphene nanoribbon 926, and the cathode 942 is connected to the drain electrode 924 by one or more additional carbon nanotubes 934, with parts except above left identical to the second embodiment shown in FIG. 6, description of identical parts, fabrication method, and different ways of construction will be omitted.

Unexplained reference numerals of 904 denotes a buffer layer, 906 denotes a first interlayer insulating film, 908 denotes a semiconductor layer, 910 denotes a gate insulating film, 912 denotes a second interlayer insulating film, 914 denotes a third interlayer insulating film, 916 denotes a protective film, 918 denotes an encapsulation substrate, 920 denotes a gate electrode, 922 denotes a source electrode, 924 denotes a drain electrode, 926 denotes a graphene nanoribbon as FET channel, and 928 denotes an electrode line.

Further unexplained reference numerals of 944 denotes an electron transport layer, 946 denotes a quantum dot light-emitting layer, 948 denotes a hole transport layer, and 950 denotes a transparent anode.

However, as it becomes obvious in FIG. 9, the light emission layer 940 is thinner and has less quantum dots, which decreases its brightness. A nanolense layer 952 is formed on the anode 950, that in this case serves as a light diffuser for an area illumination to increase the brightness.

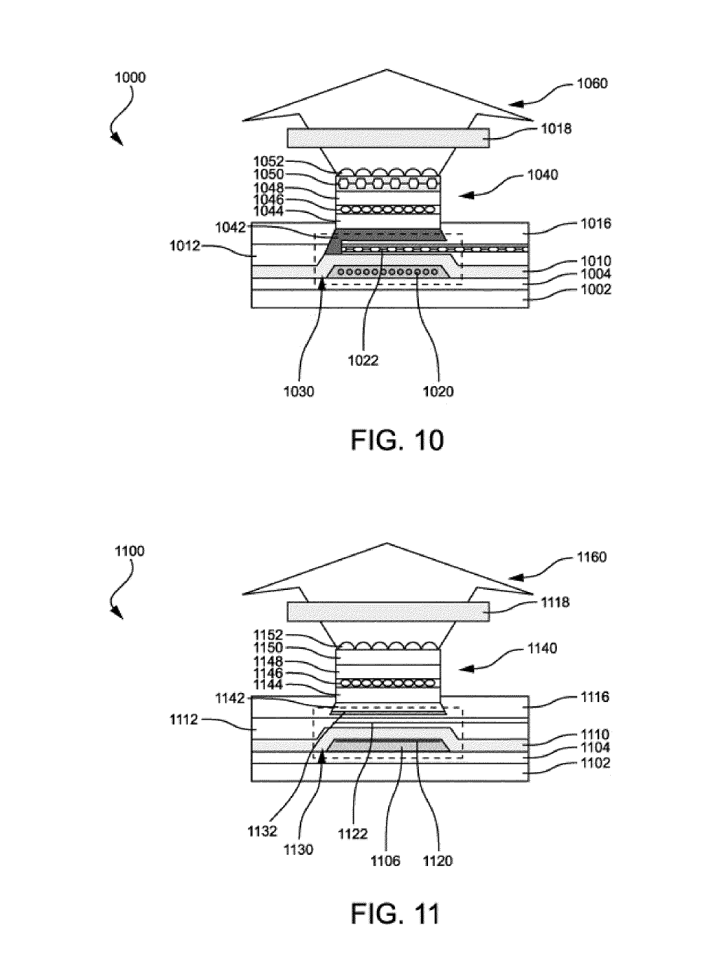

FIG. 10 illustrates a section of a QLEDD device 1000 in accordance with a sixth preferred embodiment of the present invention.

Referring to FIG. 10, the display device includes a field-effect transistor (FET) 1030 and a light emission layer 1040 to emit a beam of light 1060.

The light emission layer 1040 includes an integrated drain and cathode electrode 1042 on a first substrate 1002, a quantum dot light-emitting layer 1046 formed on the cathode 1042 to have quantum dots, a transparent anode 1050 on the quantum dot light-emitting layer 1046, and a second substrate 1018 formed opposite to the first substrate 1002.

The light emission layer 1040 can further include an electron transport layer 1044 between the cathode 1042 and the quantum dot light-emitting layer 1046, a hole transport layer 1048 between the quantum dot light-emitting layer 1046 and the anode 1050, and a nanolense layer 1052 formed on the anode 1050.

In this case, the anode 1050 is formed of a single transparent conductive metal nanowire or an array of transparent conductive metal nanowires, such as a silver nanowires or copper nanowires for example, covered with graphene for example.

The field-effect transistor (FET) 1030 is formed on the first substrate 1002. The source electrode and the FET's channel are integrated to one unit 1022, which consists of a carbon nanotube or an array of carbon nanotubes, and the drain electrode and the cathode are integrated to one unit 1042. The gate consists of an array of carbon nanotubes 1020.

Unexplained reference numerals of 1004 denotes a buffer layer, 1010 denotes a gate insulating film, 1012 denotes an interlayer insulating film, and 1016 denotes a protective film.

FIG. 11 illustrates a section of a QLEDD device 1100 in accordance with a seventh preferred embodiment of the present invention.

Referring to FIG. 11, the display device includes a field-effect transistor (FET) 1130 and a light emission layer 1140 to emit a beam of light 1160.

Because the display device in accordance with the sixth preferred embodiment of the present invention has the integrated source electrode and FET channel exchanged with a graphene nanoribbon 1122, the integrated drain and cathode electrode 1142 consists of for example a compound of graphene and silicon carbid, the gate electrode exchanged with a graphene nanoribbon 1120, and the transparent anode 1150 must not consist of a transparent conductive metal nanowire covered with graphene, with parts except above left identical to the sixth embodiment shown in FIG. 10, description of identical parts, fabrication method, and different ways of construction will be omitted. Unexplained reference numerals of 1102 denotes a substrate, 1104 denotes a buffer layer, 1106 denotes a semiconductor layer, 1110 denotes a gate insulating film, 1112 denotes an interlayer insulating film, 1116 denotes a protective film, and 1118 denotes an encapsulation substrate.

Further unexplained reference numerals of 1144 denotes an electron transport layer, 1146 denotes a quantum dot light-emitting layer, 1148 denotes a hole transport layer, and 1152 denotes a nanolense layer.

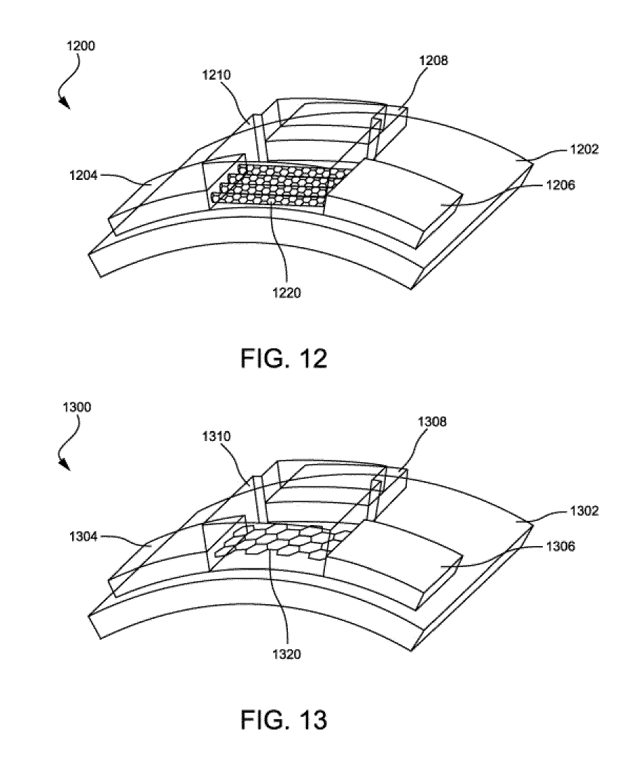

FIG. 12 illustrates a section of a QLEDD device 1200 in accordance with a eighth preferred embodiment of the present invention.

Referring to FIG. 12, the display device includes a flexible substrate 1202, a field-effect transistor (FET) with a source electrode 1204, a drain electrode 1206, and a gate electrode 1208, an array of carbon nanotubes 1220 as channel of the FET, and a carbon based, quantum dot light emission layer 1210.

However, the carbon based, quantum dot light emission layer 1210 is not shown and described, because many possibilities exist for a person skilled in the arts to construct a carbon based, quantum dot light-emitting diode device on top of an FET shown in FIG. 12. For example, more parts of an FET can be based on carbon allotropes and carbon based compounds, and formed with the parts of the carbon based, quantum dot light emission layer 1210 as one unit.

The flexible substrate 1202 can be formed from at least one material selected from a material group, which includes polymers, under consideration of thermal and mechanical characteristics. A specific material group of polymers comprises thermoplastic polymers having an index of refraction of 1.4 to 1.6, a tensile modulus of elasticity of 2300 to 3200 N/mm&sup2, and a tensile strength of 60 to 75 N/mn&sup2. This specification includes materials such as for example polymethyl methacrylate (PMMA) and polycarbonate (PC).

The display device shown in FIG. 12 was described before in the German Utility Model Application Ser. No. 20 2013 011 466.5, filed Dec. 23, 2013, and entitled “Elektronische Anzeige, die auf der nanohalbleiterkristallbasierten beziehungsweise quantenpunktbaseirten, lichtemittierenden Diode (kurz QLED) basiert”, that is hereby referenced.

FIG. 13 illustrates a section of a QLEDD device 1300 in accordance with a ninth preferred embodiment of the present invention.

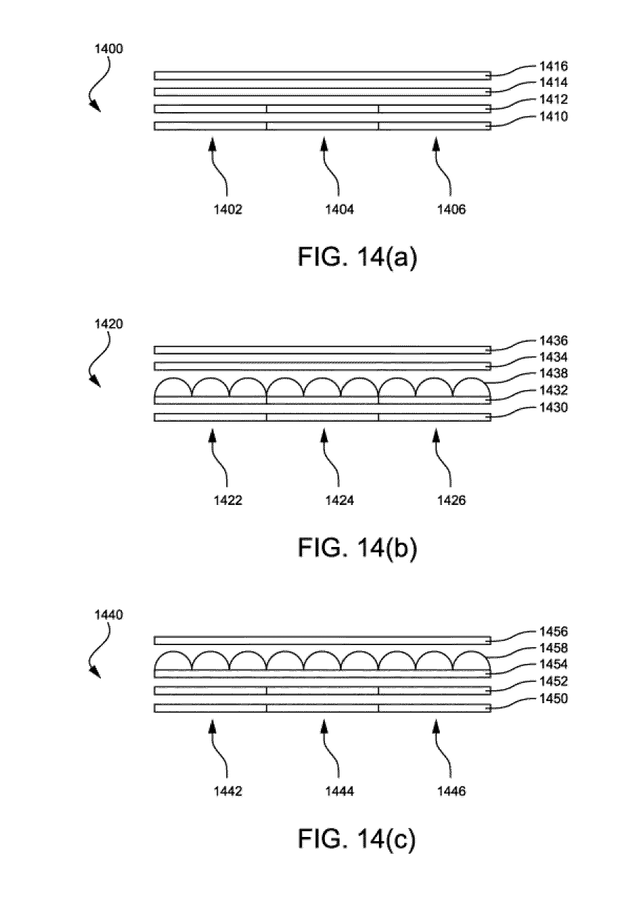

Referring to FIG. 13, the display device includes a flexible substrate 1302, a field-effect transistor (FET) with a source electrode 1304, a drain electrode 1306, and a gate electrode 1308, a graphene nanoribbon 1320 as channel of the FET, and a carbon based, quantum dot light emission layer 1310. FIGS. 14(a), 14(b), and 14(c) illustrate cross-sectional views showing an abstracted single pixel with three subpixels of a QLEDD device.

Referring to FIG. 14(a), a single pixel 1400 with a red subpixel 1402, a green subpixel 1404, and a blue subpixel 1406 of a graphene based, quantum dot based, light-emitting diode display (GQLEDD) device on substrate 1410 is illustrated as a layer model, that includes the layers with field-effect transistors (FETs) made of for example a carbon allotrope or/and a compound of a carbon allotrope and silicon, and also graphene based, quantum dot light-emitting diode (GQLED) devices 1412, polarizer 1414, as well as encapsulation substrate with scratch-resistant coating 1416.

Referring to FIG. 14(b), a single pixel 1420 with a red subpixel 1422, a green subpixel 1424, and a blue subpixel 1426 of a graphene based, quantum dot based, light-emitting diode display (GQLEDD) device on substrate 1430 is illustrated as a layer model, that includes the layers with field-effect transistors (FETs) made of for example a carbon allotrope or/and a compound of a carbon allotrope and silicon, and also graphene based, quantum dot light-emitting diode (GQLED) devices 1432, polarizer 1434, as well as encapsulation substrate with scratch-resistant coating 1436.

In addition, a layer with nanolenses 1438 is formed between the GQLED layer 1432 and the polarizer layer 1434. The layer with nanolenses 1438 serves as a light diffuser for an area illumination.

Referring to FIG. 14(c), a single pixel 1440 with a red subpixel 1442, a green subpixel 1444, and a blue subpixel 1446 of a graphene based, quantum dot based, light-emitting diode display (GQLEDD) device on substrate 1450 is illustrated as a layer model, that includes the layers with field-effect transistors (FETs) made of for example a carbon allotrope or/and a compound of a carbon allotrope and silicon, and also graphene based, quantum dot light-emitting diode (GQLED) devices 1452, polarizer 1454, as well as encapsulation substrate with scratch-resistant coating 1456.

In addition, a layer with nanolenses 1458 is formed between the polarizer layer 1454 and the encapsulation substrate layer with scratch-resistant coating 1456.

It should be trivial for any person skilled in the art, to which the invention appertains, to use carbon nanotube based, quantum dot based, light-emitting diode (CNTQLED) devices as well instead of graphene based, quantum dot based, light-emitting diode (GQLED) devices.

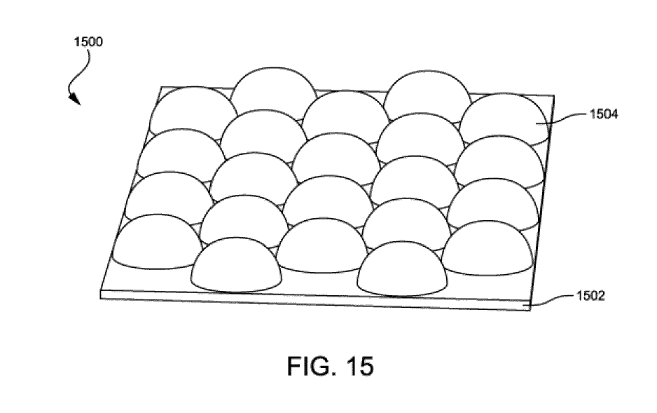

FIG. 15 illustrates a section of a QLEDD device 1500 as perspective view and shows a light emission layer with carbon based, quantum dot based, light-emitting diode devices 1504 and a layer with nanolenses 1504 formed on the light emission layer 1502.

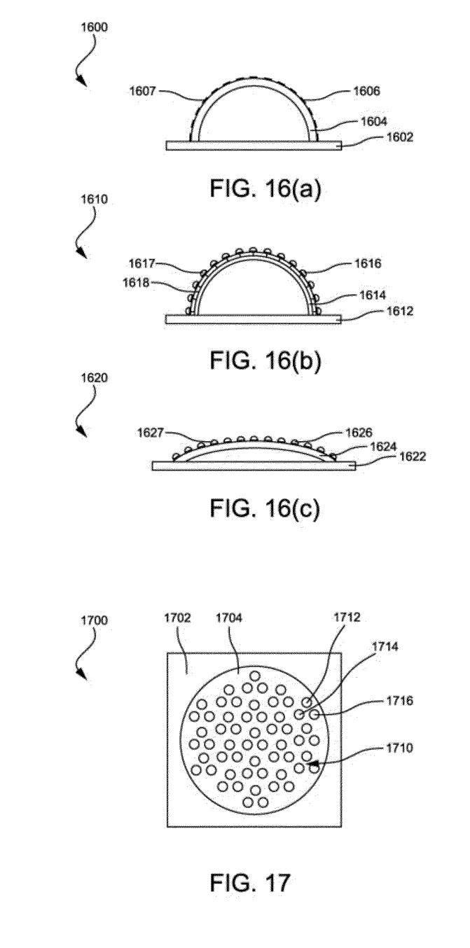

The sections of a QLEDD device shown in FIGS. 14(b) and 14(c), and also in FIG. 15 were described before in the German Utility Model Application Ser. No. 20 2013 011 005.8, filed Dec. 16, 2013, and entitled “Elektronische Anzeige, die auf der nanohalbleiterkristallbasierten beziehungsweise quantenpunktbaseirten, lichtemittierenden Diode (kurz QLED) basiert”, that is hereby referenced. FIGS. 16(a), 16(b), and 16(c) illustrate cross-section views showing a section of a QLEDD device with a carbon based, quantum dot light-emitting diode device, that emits light in different directions.

Referring to FIG. 16(a), a basic structure of a light-emitting component 1600 includes a substrate 1602, a layer with spherical shape 1604, and light-emitting individual components 1606, 1607 arranged in a faceted way on the layer with spherical shape 1604.

In this case, the light-emitting individual components 1606, 1607 are controlled together.

Referring to FIG. 16(b), a basic structure of a light-emitting component 1610 includes a substrate 1612, a layer with spherical shape 1614, light-emitting individual components with nanolense 1616, 1617 arranged in a faceted way on the layer with spherical shape 1614, and a layer with field-effect transistors and electrodes 1618.

In this case, the light-emitting individual components 1616, 1617 can be controlled individually.

Referring to FIG. 16(c), a basic structure of a light-emitting component 1620 includes a substrate 1622, a layer with spherical shape 1624, light-emitting individual components with nanolense 1626, 1627 arranged on the layer with spherical shape 1624 in a faceted way, and a layer with field-effect transistors and electrodes 1628.

In this case, the light-emitting individual components 1626, 1627 are controlled together and the layer with spherical shape 1624 has a larger radius compared to for example the layer with spherical shape 1604 shown in FIG. 16(a) and the layer with spherical shape 1614 shown in FIG. 16(b), which results in a different light beam radiation angle not shown in FIG. 16(c).

FIG. 17 illustrate a top view showing a section of a QLEDD device with a light-emitting diode device, that emits light in different directions.

Referring to FIG. 17, the display device includes a substrate 1702, a layer with spherical shape 1704, and multiple light-emitting individual component assemblies 1710 arranged on the spherical shape 1704 in a faceted way.

In this instance, a single light-emitting individual component assembly 1710 includes a red light emitting individual component 1712, a green light emitting individual component 1714, and a blue light emitting individual component 1716.

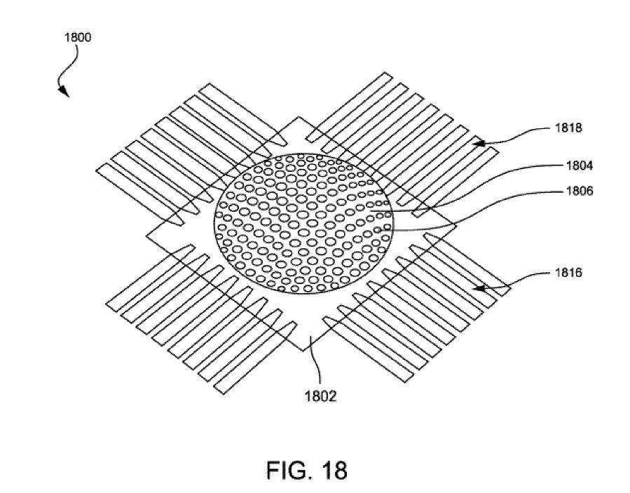

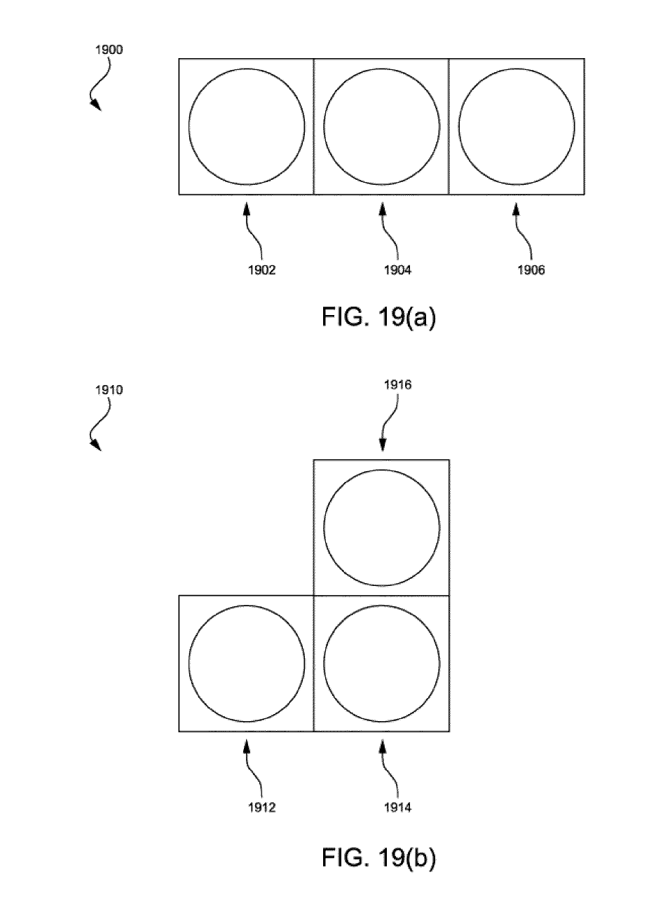

FIG. 18 illustrate a perspective view showing a section of a QLEDD device with a light-emitting diode device, that emits light in different directions.

Referring to FIG. 18, the display device includes a substrate 1802, a layer with spherical shape 1804, multiple light-emitting individual component assemblies 1810 arranged on the layer with spherical shape 1804, and scan lines 1816, data lines 1818, and power lines (not shown).

FIGS. 19(a) and 19(b) illustrate top views showing a section of a QLEDD device with potential arrangements of three light-emitting components, that emit light in different directions, as three pixel regions of the QLEDD device.

Referring to FIG. 19(a), an arrangement of three light-emitting components 1900 includes a red light emitting individual component 1902, a green light emitting individual component 1904, and a blue light emitting individual component 1906. In this instance, the three light-emitting components are arranged in a row.

Referring to FIG. 19(b), an arrangement of three light-emitting components 1910 includes a red light emitting individual component 1912, a green light emitting individual component 1914, and a blue light emitting individual component 1916. In this instance, the a first light-emitting component 1912 is arranged side by side with a second light-emitting component 1914, and a third light-emitting component 1916 is arranged to another side of the second light-emitting component 1914 in such a way, that the three light-emitting components are not arranged in a row.

As it becomes obvious in FIGS. 19(a) and 19(b), many other arrangements of light-emitting components are possible, which will not be described here.

Using light-emitting diodes, that emit light in different directions, as shown in FIGS. 16(a), 16(b), and 16(c), as well as FIG. 17, FIG. 18, and FIGS. 19(a) and 19(b), has the advantage that hereby a QLEDD device can be constructed in different ways, like for example a multiscopic display device, which can be viewed from different viewing angles simultaneously.

The display devices shown in FIGS. 16(a), 16(b), and 16(c), as well as FIG. 17, FIG. 18, and FIGS. 19(a) and 19(b) were described before in the German Utility Model Application Ser. No. 20 2013 010 994.7, filed Dec. 15, 2013, and entitled “Lichtemittierendes Bauelement, das eine Fläche besitzt, die in einer sphärischen Form ausgeführt ist” that is hereby cross referenced.

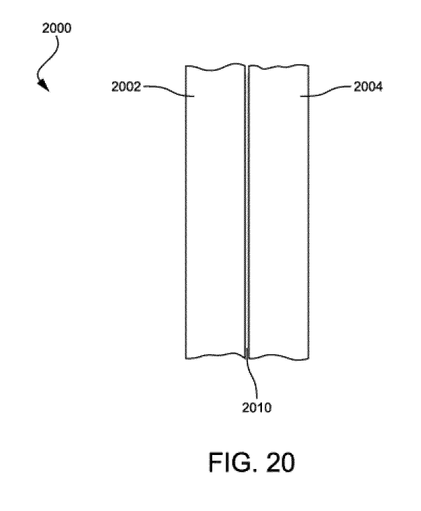

FIG. 20 is a cross-sectional view showing a section of an application of a QLEDD device.

Referring to FIG. 20, the application of the QLEDD device includes a first glass layer 2002 and a second glass layer 2004 opposite to the first glass layer 2002, the QLEDD device 2010 being sandwiched between the first glass layer 2002 and the second glass layer 2004.

And, though not shown, sealant is placed between edges of the first glass layer 2002 and the second glass layer 2004 for bonding the two layers. This is for protecting the QLEDD device 2010 from water or other external environment.

The application of the QLEDD device could be a laminated glass or a laminated safety glass.

Although it is not shown in the drawings, the display device layers can further include adhesive layers used to adhere other layers to each other. Each of the adhesive layers can be formed from one of an epoxy based resin and an acrylate based resin. polyvinyl butyral (PVB)

In the case that PVB is applied as a protective interlayer the laminated safety glass can be a front or rear windscreen, or the pane of a side window of a vehicle for example.

As has been described, the carbon based, quantum dot light-emitting diode display device of the present invention has the following advantages.

By using a carbon allotrope or/and carbon based compounds QLEDD devices can be constructed that permit to reduce the driving voltage, improve the electric power efficiency, reduce the power consumption, increase the display resolution, increase the refresh rate, or/and enhance the quality of transparency and sharpness of see-through variants of the QLEDD device.

It should be understood that numerous other modifications and embodiments can be devised by those skilled in the art that will fall within the spirit and scope of the principles of this disclosure. In other words, although embodiments have been described with reference to a number of illustrative embodiments thereof, this disclosure is not limited to those. Accordingly, the scope of the present disclosure shall be determined only by the appended claims and their equivalents. In addition, variations and modifications in the component parts and/or arrangements, alternative uses must be regarded as included in the appended claims.

1. A quantum dot light-emitting diode display device comprising:
a substrate;
a light emission diode layer stacked on the substrate and configured to emit light,
the light emission diode layer including a cathode,
a quantum dot light-emitting layer formed on the cathode to include quantum dots, and
an anode formed on the quantum dot light-emitting layer;
at least one electrode of the quantum dot light emission diode layer based on carbon;
at least one scan line;
at least one data line;
at least one power line; and
a field-effect transistor connected to the light emission diode layer.

2. The quantum dot light-emitting diode display device of claim 1, wherein
the device includes a stacked layer structure of at least one organic film and at least one inorganic film.

3. The quantum dot light-emitting diode display device of claim 1, further comprising:
an electron transport layer between the cathode and the quantum dot light-emitting layer.

4. The quantum dot light-emitting diode display device of claim 1, further comprising:
a hole transport layer between the anode and the quantum dot light-emitting layer.

5. The quantum dot light-emitting diode display device of claim 1, wherein
at least one electrode of the quantum dot light emission diode layer is transparent.

6. The quantum dot light-emitting diode display device of claim 1, wherein
at least one electrode of the quantum dot light emission diode layer is based on the carbon allotrope graphene.

7. The quantum dot light-emitting diode display device of claim 1, wherein
at least one electrode of the quantum dot light emission diode layer is based on the carbon allotrope carbon nanotube.

8. The quantum dot light-emitting diode display device of claim 1, wherein
at least one layer of the quantum dot light emission diode layer is based on a composite of graphene and silicon compound.

9. The quantum dot light-emitting diode display device of claim 1, wherein
at least one electrode of the quantum dot light emission diode layer is made of a metal nanowire covered with graphene.

10. The quantum dot light-emitting diode display device of claim 1, wherein
at least one electrode of the quantum dot light emission diode layer is made of a semiconductor nanowire covered with graphene.

11. The quantum dot light-emitting diode display device of claim 1, wherein
the field-effect transistor is a thin-film transistor (TFT).

12. The quantum dot light-emitting diode display device of claim 1, wherein
at least one electrode of the field-effect transistor is based on the carbon allotrope graphene.

13. The quantum dot light-emitting diode display device of claim 1, wherein
at least one electrode of the field-effect transistor is based on the carbon allotrope carbon nanotube.

14. The quantum dot light-emitting diode display device of claim 1, wherein
at least one electrode of the field-effect transistor is made of a metal nanowire covered with graphene.

15. The quantum dot light-emitting diode display device of claim 1, wherein
at least one electrode of the field-effect transistor is made of a semiconductor nanowire covered with graphene.

16. The quantum dot light-emitting diode display device of claim 1, wherein
the electron channel of the field-effect transistor is based on the carbon allotrope graphene.

17. The quantum dot light-emitting diode display device of claim 1, wherein
at least one layer of the field-effect transistor is based on a composite of graphene and silicon carbide compound.

18. The quantum dot light-emitting diode display device of claim 1, wherein
the electron channel of the field-effect transistor is based on the carbon allotrope carbon nanotube.

19. The quantum dot light-emitting diode display device of claim 1, wherein
at least one electrode of the quantum dot light emission diode layer and at least one drain electrode of a field-effect transistor are one unit.

20. The quantum dot light-emitting diode display device of claim 1, wherein
at least one scan line is based on the carbon allotrope graphene.

21. The quantum dot light-emitting diode display device of claim 1, wherein
at least one data line is based on the carbon allotrope graphene.

22. The quantum dot light-emitting diode display device of claim 1, wherein
at least one power line is based on the carbon allotrope graphene.

23. The quantum dot light-emitting diode display device of claim 1, wherein
at least one data line is based on the carbon allotrope carbon nanotube.

24. The quantum dot light-emitting diode display device of claim 1, wherein
at least one scan line is based on the carbon allotrope carbon nanotube.

25. The quantum dot light-emitting diode display device of claim 1, wherein
at least one power line is based on the carbon allotrope carbon nanotube.

26. The quantum dot light-emitting diode display device of claim 1, further comprising:
a second substrate opposite to the first substrate,
the second substrate having a color filter layer.

27. The quantum dot light-emitting diode display device of claim 1 further comprising:
a layer of nanolenses.

28. The quantum dot light-emitting diode display device of claim 1 further comprising:
a scratch-resistant coating.

29. The quantum dot light-emitting diode display device of claim 1, wherein
the light emission diode layer has at least one light-emitting diode with a surface realized in a spherical shape; and
at least two individual light-emitting quantum dots,
the quantum dots being arranged on the spherical diode surface in a faceted way.

30. The quantum dot light-emitting diode display device of claim 1, wherein
the light emission diode layer has at at least one display area with a surface realized in a spherical shape; and
at least two individual quantum dot light-emitting diode devices,
the quantum dot light-emitting diode devices being arranged on the spherical are surface in a faceted way.

31. The quantum dot light-emitting diode display device of claim 1, wherein
the substrate is flexible.

32. The quantum dot light-emitting diode display device of claim 1, wherein
the substrate is bendable.

33. The quantum dot light-emitting diode display device of claim 1, wherein
the substrate is a thermoplastic polymer,
the thermoplastic polymer having an index of refraction of 1,4 to 1,6, a tensile modulus of elasticity of 2300 to 3200 N/mm², and a tensile strength of 60 to 75 N/mn².

34. The quantum dot light-emitting diode display device of claim 1, further comprising:
a first glass layer; and
a second glass layer opposite to the first glass layer,
the display being sandwiched between the first glass layer and the second glass layer.

35. The quantum dot light-emitting diode display device of claim 1, further comprising:
an adhesive layer based on polyvinyl butyral (PVB).
